(19) United States
(12) Patent Application Publication
(10) Pub. No.: US 2026/0047071 A1
(43) Pub. Date: Feb. 12, 2026

(54) SEMICONDUCTOR DEVICE AND FABRICATION METHOD THEREOF

(71) Applicant: Yangtze Memory Technologies Co., Ltd., Wuhan (CN)

(72) Inventors: Yu ZHANG, Wuhan (CN); Gang LIU, Wuhan (CN); Junbo FENG, Wuhan (CN); Bolun WANG, Wuhan (CN); Yu GAO, Wuhan (CN); Quanshan LV, Wuhan (CN); Lei JIN, Wuhan (CN); Zongliang HUO, Wuhan (CN)

(21) Appl. No.: 18/906,909

(22) Filed: Oct. 4, 2024

Related U.S. Application Data
(63) Continuation of application No. PCT/CN2024/110995, filed on Aug. 9, 2024.

(51) Int. Cl. H10B 12/00; H01L 23/00; H01L 25/065; H01L 25/18; H10B 80/00

(52) U.S. Cl. CPC H10B 12/315; H01L 24/08; H01L 25/0657; H01L 25/18; H10B 12/05; H10B 80/00; H01L 2224/08145; H01L 2924/1431; H01L 2924/1436

(57) ABSTRACT

Methods, devices, systems, and techniques for managing conductive structure in semiconductor devices are provided. In one aspect, a semiconductor device includes a plurality of memory cells. Each memory cell of the plurality of memory cells includes a transistor having a gate structure that extends along a first direction in a first trench structure. The semiconductor device further includes a conductive structure in a second trench structure between transistors of a first memory cell and a second memory cell. The transistors of the first memory cell and the second memory cell have corresponding first terminal structures, a same semiconductor body, and a same second terminal structure. The conductive structure is in contact with the semiconductor body of the transistors of the first memory cell and the second memory cell. The first trench structure has a greater length than the second trench structure along the first direction.

### CROSS-REFERENCE TO RELATED APPLICATIONS

This application is a continuation of International Application No. PCT/CN2024/110995, filed on Aug. 9, 2024, the disclosure of which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures, e.g., vertical transistors.

### SUMMARY

The present disclosure describes methods, devices, systems and techniques for managing vertical structures in three-dimensional (3D) semiconductor devices.

One aspect of the present disclosure features a semiconductor device. The semiconductor device includes a plurality of memory cells, where a memory cell of the plurality of memory cells comprises a transistor having a gate structure that extends along a first direction in a first trench structure, and a conductive structure in a second trench structure between transistors of a first memory cell and a second memory cell, where the transistors of the first memory cell and the second memory cell have corresponding first terminal structures, a same semiconductor body, and a same second terminal structure, and where the conductive structure is in contact with the semiconductor body of the transistors of the first memory cell and the second memory cell, wherein the first trench structure has a greater length than the second trench structure along the first direction.

In some implementations, along the first direction, an end of the gate structure of the transistor of the memory cell is farther from the first terminal structure of the transistor of the memory cell than an end of second trench structure.

In some implementations, a length of the first trench structure is greater than a length of the second trench structure along a second direction perpendicular to the first direction.

In some implementations, the semiconductor body of the memory cells comprises opposite ends along the first direction, where the first terminal structure and the second terminal structure are at the opposite ends of the semiconductor body of the memory cell, respectively, and where the second trench structure is between two adjacent first trench structures along a second direction perpendicular to the first direction.

In some implementations, the semiconductor device includes a third memory cell, where the first memory cell is between the second memory cell and the third memory cell along a second direction perpendicular to the first direction, and where the first trench structure includes two gate structures of two transistors of the first memory cell and the third memory cell, where the two gate structures are isolated by an isolation material filled in the first trench structure.

In some implementations, the conductive structure is isolated from the first terminal structure by a dielectric material along a second direction perpendicular to the first direction.

In some implementations, the conductive structure includes a semiconductor material, and where the second trench structure further includes a dielectric body stacked on the conductive structure along the first direction.

In some implementations, the conductive structure includes a metallic material, where the second trench structure further includes a dielectric body stacked on the conductive structure along the first direction, and where the semiconductor device further includes an ohmic contact between the metallic material and the semiconductor body.

In some implementations, the conductive structure in the second trench structure is coupled to an interconnect structure through a coupling-out structure.

In some implementations, the first trench structure and the second trench structure extend along a second direction perpendicular to the first direction, and where the semiconductor device further includes one or more third trench structures extending through the semiconductor device along the first direction and being spaced from each other along a third direction perpendicular to the first direction and the second direction.

In some implementations, the one or more third trench structures are filled with an isolating material, and where the first trench structure includes the isolating material filled around the gate structure, and the second trench structure includes the isolating material stacked on the conductive structure along the first direction.

Another aspect of the present disclosure features a method of forming a semiconductor device. The method includes forming a plurality of memory cells in a semiconductor substrate, where a memory cell of the plurality of memory cells includes a transistor having a gate structure that extends along a first direction in a first trench structure. The method further includes forming a conductive structure in a second trench structure between transistors of a first memory cell and a second memory cell, where the transistors of the first memory cell and the second memory cell have corresponding first terminal structures, a same semiconductor body, and a same second terminal structure, and where the conductive structure is in contact with the semiconductor body of the transistors of the first memory cell and the second memory cell, where the first trench structure has a greater length than the second trench structure along the first direction.

In some implementations, the semiconductor body of the memory cells comprises opposite ends along the first direction, where the first terminal structure and the second terminal structure are at the opposite ends of the semiconductor body of the memory cell, respectively, and where the second trench structure is between two adjacent first trench structures along a second direction perpendicular to the first direction.

In some implementations, forming the conductive structure includes: etching the semiconductor substrate along the first direction to form a trench, and depositing a semiconductor material in the trench along the first direction, where a length of the semiconductor material is no greater than a length of the semiconductor body along the first direction.

In some implementations, a portion of the semiconductor material is diffused into the semiconductor body to form a conductive contact between the semiconductor material and the semiconductor body, and where the conductive structure is in contact with a part of the semiconductor body that is closer to the second terminal structure than the first terminal structure along the first direction.

In some implementations, forming the conductive structure includes: etching the semiconductor substrate along the first direction to form a trench, implanting conductive ions into the semiconductor body at a bottom of the trench to form a conductive contact, and depositing a metallic material on the conductive contact in the trench to form the conductive structure, where a length of the metallic material is no greater than a length of the semiconductor body along the first direction.

In some implementations, the method further includes: forming the first trench structure comprising the gate structure, where the first trench structure and the second trench structure are at different positions along a second direction perpendicular to the first direction, and where the gate structure extends along the first direction in the first trench structure, and wherein, along the first direction, an end of the gate structure of the transistor of the memory cell is farther from the first terminal structure of the transistor of the memory cell than an end of second trench structure.

In some implementations, the first trench structure and the second trench structure extend along a second direction perpendicular to the first direction, and where the method further includes: forming one or more third trench structures extending through the semiconductor substrate along the first direction and being spaced from each other along a third direction perpendicular to the first direction and the second direction.

In some implementations, the one or more third trench structures are filled with an isolating material, and where the first trench structure includes the isolating material filled around the gate structure, and the second trench structure includes the isolating material stacked on the conductive structure along the first direction.

In some implementations, the method further includes: forming a coupling-out structure, where the conductive structure in the second trench structure is coupled to an interconnect structure through the coupling-out structure.

A further aspect of the present disclosure features a memory system. The memory system includes a memory device and a memory controller coupled to the memory device and configured to control the memory device. The memory device includes a plurality of memory cells, where a memory cell of the plurality of memory cells includes a transistor having a gate structure that extends along a first direction in a first trench structure; and a conductive structure in a second trench structure between transistors of a first memory cell and a second memory cell, where the transistors of the first memory cell and the second memory cell have corresponding first terminal structures, a same semiconductor body, and a same second terminal structure, and where the conductive structure is in contact with the semiconductor body of the transistors of the first memory cell and the second memory cell, where the first trench structure has a greater length than the second trench structure along the first direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example 3D semiconductor device.

FIG. 2 illustrates a perspective view of an example 3D semiconductor device.

FIG. 3A illustrates a cross-sectional view of example 3D semiconductor devices including semiconductor conductive structure.

FIG. 3B illustrates a top view of example 3D semiconductor devices of FIG. 3A.

FIG. 3C a cross-sectional view of example 3D semiconductor devices including metal conductive structure.

FIG. 3D illustrates a top view of example 3D semiconductor devices of FIG. 3C.

FIGS. 4A to 4D show cross-sectional views of structures of a 3D semiconductor device of FIG. 3A at various stages of a fabrication process.

FIGS. 5A to 5D show cross-sectional views of structures of a 3D semiconductor device of FIG. 3B at various stages of a fabrication process.

FIGS. 6A-6B illustrate a perspective view of an example 3D semiconductor device.

FIG. 7 illustrates a flow chart of an example process of manufacturing a semiconductor structure.

FIG. 8 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a DRAM memory) can be formed to have a vertical channel selector tube and a high aspect ratio. The vertical channel selector tube and the high aspect ratio of such memory devices may pose challenges to the manufacturing process. For example, a vertical channel selector tube generally has a floating body, which leads to an accumulation of the charges created in the source-leakage junction in the body region of the transistor body. In other words, the vertical channel selector tube may increase channel leakage. In another example, the high aspect ratio may pose challenges in controlling the leakage current. Therefore, a vertical channel structure that can solve the aforementioned issues is desirable.

In one or more implementations of the present disclosure, an example semiconductor device is provided. The semiconductor device includes a plurality of memory cells, where a memory cell of the plurality of memory cells includes a transistor having a semiconductor body, a first terminal structure, a second terminal structure, and a gate structure, where the gate structure extends along a first direction in a first trench structure. The semiconductor device further includes a conductive structure in a second trench structure between transistors of a first memory cell and a second memory cell, the conductive structure being in contact with semiconductor bodies of the transistors of the first memory cell and the second memory cells, where the first trench structure has a greater length than the second trench structure along the first direction.

Implementations of the present disclosure can provide one or more of the following technical advantages and/or benefits. For example, by using a conductive structure between two adjacent memory cells, charges build-up in the floating body can be reduced, thereby mitigating the floating body effect in the vertical channel selector tube. By reducing the length of the second trench between the first memory cell and the second memory cell, the semiconductor bodies of the two transistors of the first memory cell and the second memory cell are connected together, reducing the overall manufacturing complexity and cost, and improving the reliability of the memory cells. Moreover, by arranging the gate structure and the conductive structure in two different trenches on opposite sides of the semiconductor body of the transistor, the overall manufacturing complexity of the semiconductor structure can be reduced.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

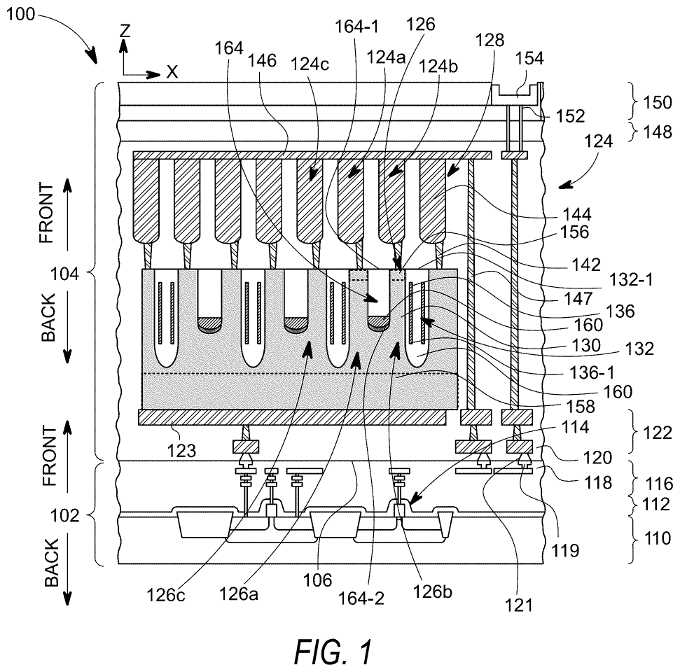

It is noted that X, Y, and Z axes (also referred to as X, Y, and Z directions) are included in FIG. 1 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlayer dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor (T) and one capacitor (C). It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 extending vertically (in the Z direction), and a gate structure 136 extends along the Z direction in a first trench structure 132. The first trench structure 132 is in contact with one side of the semiconductor body 130. In some implementations, the first trench structure 132 is filled with a dielectric material. In a single-gate vertical transistor, the semiconductor body 130 can have a cuboid shape or a cylinder shape. In some implementations, the vertical transistor 126 has a structure including two or more gates, e.g., a two-gates structure, a three-gates structure, or a gate all around (GAA) structure. In some implementations, the gate structure 136 includes a gate electrode and a gate dielectric laterally between the gate electrode and the semiconductor body 130 in a bit line direction (e.g., in the Y direction). In some implementations, the vertical transistor 126 can have a first terminal structure 156 in the positive z-direction and a second terminal structure 158 opposite the first terminal structure 156 in the negative z-direction, as shown in FIG. 1. Each vertical transistor 126 of the DRAM cell 124 can include a conductive structure 160 in a second trench structure 164. The second trench structure 164 is between a first vertical transistor 126a of a first memory cell 124a and a second vertical transistor 126b of a second memory cell 124b.

The conductive structure 160 is connected to the semiconductor bodies 130 of the vertical transistors 126a and 126b of the first memory cell 124a and the second memory cell 124b. In some implementations, the transistors 126a and 126b of first memory cell 124a and the second memory cell 124b have corresponding first terminal structures 156, a same semiconductor body 130, and a same second terminal structure 158, and the conductive structure 160 is in contact with the semiconductor body 130 of the transistors 126a and 126b of first memory cell 124a and the second memory cell 124b. In some implementations, the second trench structure 164 can be filled with an isolation material. In some implementations, as shown in FIG. 1, the first trench structure 132 has a grater length than the second trench structure 164 along the Z direction. In some implementations, the semiconductor bodies 130 of the vertical transistors 126a and 126b of the first memory cell 124a and the second memory cell 124b are connected together along a horizontal direction (e.g., the X direction) perpendicular to the Z direction. In some implementations, as shown in FIG. 1, a length of an end 132-1 of the first trench structure 132 and a length of an end 164-1 of the second trench structure 164 are identical to each other along the X direction.

As shown in FIG. 1, in some implementations, the semiconductor body 130 of the vertical transistor 126 of each memory cell 124 includes opposite ends along the Z direction. In some implementations, the first terminal structure 156 of the vertical transistor 126 and the second terminal structure 158 of the vertical transistor 126 are at the opposite ends of the semiconductor body 130 of the memory cell 124 along the Z direction, and the second trench structure 164 is between two adjacent first trench structures 132 along the X direction. In some implementations, as shown in FIG. 1, an end 136-1 of the gate structure 136 of the vertical transistor 126 of the memory cell 124 is farther from the first terminal structure 156 of the vertical transistor 126 of the memory cell 124 than an end 164-2 of the second trench structure 164.

As shown in FIG. 1, the semiconductor device 100 can include a third memory cell 124c. In some implementations, the first memory cell 124a is between the second memory cell 124b and the third memory cell 124c along the X direction. In some implementations, as shown in FIG. 1, the first trench structure 132 can include two gate structures 136 of two vertical transistors 126a and 126c of the first memory cell 124a and the third memory cell 124c. In some implementations, as shown in FIG. 1, a thickness of the conductive structure 160 is no greater than a thickness of the semiconductor body 130 along the Z direction, and where the conductive structure 160 is connected to a part of the semiconductor body 130 that is closer to the second terminal structure 158 than the first terminal structure 156 along the Z direction. In some implementations, a thickness of the conductive structure 160 is no greater than a thickness of the semiconductor body 130 along the Z direction, and the conductive structure 160 is connected to a part of the semiconductor body 130 that is closer to the second terminal structure 158 than the first terminal structure 156 along the Z direction. In some implementations, the conductive structure 160 is isolated from the first terminal structure 156 by a dielectric material along the X direction. In some implementations, as shown in FIG. 1, the first terminal structure 156 is coupled to the capacitor 128 and the second terminal structure 158 is couple to the bit line 123. In some implementations, the first terminal structure 156 can be a source structure and the second terminal structure 158 can be a drain structure. In some implementations, the semiconductor bodies 130 of the first memory cell 124a and the second memory cell 124b form a single semiconductor body 130. In some implementations, the second trench structure 164 is surrounded by the single semiconductor body 130. In some implementations, the second terminal structures 158 of the memory cells 124 form a single second terminal structure 158. The second terminal structure 158 is connected to the corresponding bit line 123. In some implementations, the transistors 126 of the two adjacent memory cells 124a, 124b have respective first terminal structures 156 coupled to respective capacitors 128b, a same semiconductor body 210, and a same second terminal structure 158.

In some implementations, the semiconductor body 130 includes a semiconductor material, such as single crystalline silicon, polysilicon, amorphous silicon, Ge, any other semiconductor material, or any combinations thereof. In one example, semiconductor body 130 may include single crystalline silicon. The first terminal structure 156 and the second terminal structure 158 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between the second terminal structure 158 of the vertical transistor 126 and the bit line 123 as the bit line contact or the first terminal structure 156 of the vertical transistor 126 and the first electrode of the capacitor 128 as capacitor contact 142 to reduce the contact resistance. In some implementations, gate dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode includes a conductive material including, but not limited to W, Co, Cu, Al, TiN, TaN, polysilicon, silicide, or any combination thereof. In some implementations, the gate electrode includes multiple conductive layers, such as a W layer over a TiN layer. In one example, the gate structure 136 may be a “gate oxide/gate poly” gate in which the gate dielectric includes silicon oxide and gate electrode includes doped polysilicon. In another example, gate structure 136 may be an HKMG in which the gate dielectric includes a high-k dielectric and the gate electrode includes a metal.

As described above, since the gate structure 136 may be part of a word line or extend in the word line direction (e.g., the X direction) as a word line, the second semiconductor structure 104 of the 3D semiconductor device 100 can also include a plurality of word lines each extending in the word line direction. Each word line can be coupled to a row of DRAM cells 124. That is, the bit line 123 and the word line can extend in two perpendicular lateral directions, and the semiconductor body 130 of the vertical transistor 126 can extend in the vertical direction perpendicular to the two lateral directions in which the bit line 123 and the word line extend. Word lines are in contact with word line contacts (not shown). In some implementations, the word lines include conductive materials including, but not limited to W, Co, Cu, Al, TiN, TaN, polysilicon, silicides, or any combination thereof. In some implementations, the word line includes multiple conductive layers, such as a W layer over a TiN layer, as shown in FIG. 1.

In some implementations, as shown in FIG. 1, the vertical transistors 126 can be arranged in a mirror-symmetric manner to increase the density of the memory cells 124 in the bit line direction (the Y direction). As shown in FIG. 1, two adjacent vertical transistors 126 in the bit line direction are mirror-symmetric to one another with respect to the second trench structure 164. That is, the second semiconductor structure 104 can include a plurality of the second trench structures 160 each extending in the X direction in parallel with word lines and disposed between vertical gates of two adjacent rows of the vertical transistors 126. Each of the first trench structures can include two gate structures 136 of two memory cells. In some implementations, the rows of vertical transistors 126 separated by the second trench structure 164 are mirror-symmetric to one another with respect to the second trench structure 164. The second trench structure 164 can include the conductive structure 160 in contact with the semiconductor body and filled with dielectric materials including, but not limited to, silicon oxide, silicon nitride, silicon oxynitride, low-k dielectrics, or any combination thereof.

As shown in FIG. 1, in some implementations, a capacitor 128 includes a first electrode 144 above and coupled to the first terminal structure 156 of the vertical transistor 126 via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the z-direction), and the capacitor dielectric can be sandwiched between the electrodes. In some implementations, each first electrode is coupled to the first terminal structure 156 of a respective vertical transistor 126 in the same memory cell 124, while all second electrodes are coupled to a common plate 146 coupled to the ground, e.g., a common ground. The capacitor 128 can have a first end in the negative z-direction and a second end opposite the first end in the positive z-direction, as shown in FIG. 1. As shown in FIG. 1, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 1. In some implementations, the ILD layer in which the capacitors 128 are formed has the same dielectric material as the two ILD layers into which the semiconductor body 130 extends, such as silicon oxide.

It is understood that the structure and configuration of a capacitor 128 are not limited to the example in FIG. 1 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106 As a result, the interconnect layer 122 including bit lines 123 can be arranged close to the bonding interface 106 to reduce the interconnect routing distance and complexity.

In some implementations, the second semiconductor structure 104 further includes a substrate 148 disposed above the DRAM cells 124. The substrate 148 can be part of a carrier wafer. It is understood that in some examples, the substrate 148 may not be included in the second semiconductor structure 104.

As shown in FIG. 1, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron-or tens micron-level (e.g., between 1 μm and 100 μm).

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines and/or between semiconductor bodies 130 may be partially or fully filled with dielectrics. Although not shown, it is further understood that more than one array of DRAM cells 124 may be stacked over one another to vertically scale up the number of DRAM cells 124.

In some implementations, instead of having the substrate 148 above the DRAM cells 124 as shown in FIG. 1, the second semiconductor structure 104 includes a substrate disposed below the DRAM cells 124. The substrate can be part of a carrier wafer. The DRAM cells 124 can be formed in a front side of the substrate, and the bit lines 123 can be formed in a back side of the substrate. The bit lines 123 can be conductively coupled to the DRAM cells 124 (e.g., the terminal structures 158 of the vertical transistors 126) through the substrate.

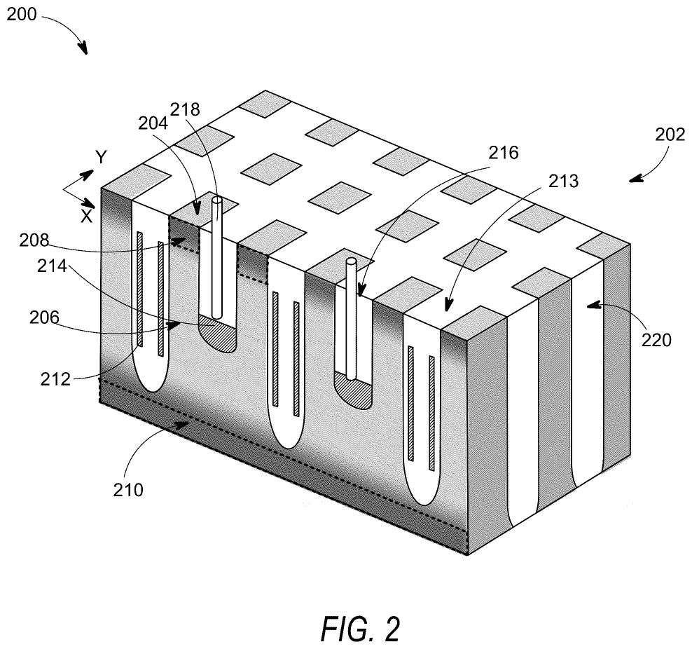

FIG. 2 shows a perspective view of an example 3D semiconductor device 200. The 3D semiconductor device can be the 3D semiconductor device 100 of FIG. 1 or a structure at an intermediate fabrication process of the 3D semiconductor device 100 of FIG. 1.

As shown in FIG. 2, the 3D semiconductor device 200 can include one or more memory cells 202. In some implementations, the memory cell 202 can be similar to, or same as the memory cell 124 of the semiconductor device 100 as shown in FIG. 1. Each memory cell can include a vertical transistor 204 having a semiconductor body 206, a first terminal structure 208, a second terminal structure 210, and a gate structure 212, where the gate structure 212 extends along a vertical direction (e.g., the Z direction) in a first trench structure 213. In some implementations, the vertical transistor 204 can include a conductive structure 214 in a second trench structure 216 between vertical transistors 204 of the two adjacent memory cells 202. In some implementations, as shown in FIG. 2, the conductive structure 214 is connected to the semiconductor bodies 206 of the vertical transistors 204 of the two adjacent memory cells 202. In some implementations, the transistors 204 of two adjacent memory cells 202 have corresponding first terminal structures 208, a same semiconductor body 206, and a same second terminal structure 210, and the conductive structure 214 is in contact with the semiconductor body 210 of the transistors 204 of the two adjacent memory cells 202. In some implementations, the first trench structure 213 has a greater length than the second trench structure 216 along the Z direction and a length of the first trench structure 213 is greater than a length of the second trench structure 216 along a horizontal direction (e.g., the X direction) perpendicular to the Z direction. In some implementations, the bottom end of the first trench structure 213 is farther away from the surface of the semiconductor device 200 closer to the first terminal structure 208 than the bottom end of the second trench structure 216 along the Z direction. In some implementations, the semiconductor bodies 206 of the vertical transistors 204 of the two adjacent memory cells 202 are connected together. In some implementations, the vertical transistor 204 can be similar to, or same as the vertical transistor 126 of the semiconductor device 100 as shown in FIG. 1. In some implementations, the semiconductor body 206 can be similar to, or same as the semiconductor body 130 of the semiconductor device 100 as shown in FIG. 1. In some implementations, the first terminal structure 208 can be similar to, or same as the first terminal structure 156 of the semiconductor device 100 as shown in FIG. 1. In some implementations, the second terminal structure 210 can be similar to, or same as the second terminal structure 158 of the semiconductor device 100 as shown in FIG. 1. In some implementations, the gate structure 212 can be similar to, or same as the gate structure 136 of the semiconductor device 100 as shown in FIG. 1. In some implementations, the first trench structure 213 can be similar to, or same as the first trench structure 132 of the semiconductor device 100 as shown in FIG. 1. In some implementations, the conductive structure 214 can be similar to, or same as the conductive structure 160 of the semiconductor device 100 as shown in FIG. 1. In some implementations, the second trench structure 216 can be similar to, or same as the second trench structure 164 of the semiconductor device 100 as shown in FIG. 1.

In some implementations, as shown in FIG. 2, the semiconductor body 206 of the memory cell 202 includes opposite ends along the Z direction. The first terminal structure 208 and the second terminal structure 210 are at the opposite ends of the semiconductor body 206 of the memory cell 202, and the second trench structure 216 are between two adjacent first trench structure 213 along the X direction. In some implementations, the conductive structure 214 in the second trench structure 216 is coupled to an interconnect structure through a coupling-out structure 218. The coupling-out structure 218 extends along the second trench structure 216 and is connected to the conductive structure 214 along the Z direction. In some implementations, the coupling-out structure 218 can be a via structure. In some implementations, the coupling-out structure 218 include conductive materials including, but not limited to W, Co, Cu, Al, TiN, TaN, polysilicon, silicides, or any combination thereof. In some implementations, the semiconductor bodies 206 of the two adjacent memory cells 202 form a single semiconductor body 206. In some implementations, the second trench structure 216 is surrounded by the single semiconductor body 206. In some implementations, the second terminal structures 210 of the memory cells 202 form a single second terminal structure 210. In some implementations, the transistors of the two adjacent memory cells 202 have respective first terminal structures 208 coupled to respective storage nodes (or capacitors), a same semiconductor body 206, and a same second terminal structure 210.

In some implementations, as shown in FIG. 2, the first trench structure 213 and the second trench structure 216 can extend along a second horizontal direction (e.g., the Y direction) perpendicular to the X direction and the Z direction. The semiconductor device 200 can include one or more third trench structures 220 extending through the semiconductor device 200 along the Z direction and being spaced from each other along the Y direction. The one or more third trench structures 220 extend along the X direction and separate the semiconductor device 200 into multiple arrays. In some implementations, the third trench structure 220 can be filled with a first dielectric material, such as silicon oxide, silicon nitride, or high-k dielectrics including, but not limited to, Al₂O₃, HfO₂, Ta₂O₅, ZrO₂, TiO₂, or any combination thereof. In some implementations, the first trench structure 213 can be filled with a second dielectric material around the gate structure 212, and the second trench structure 216 can be filled with a third dielectric material stacked on the conductive structure 214 along the Z direction. In some implementations, the second dielectric material and the third dielectric material can be a same material as the first dielectric material.

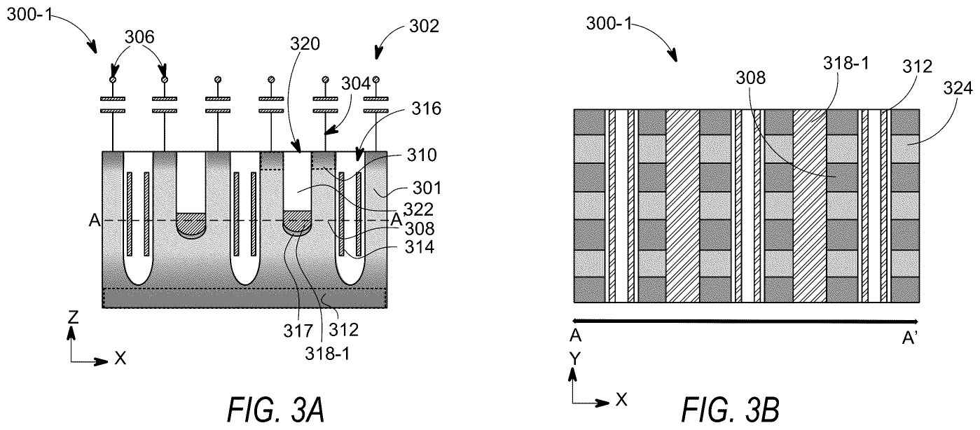

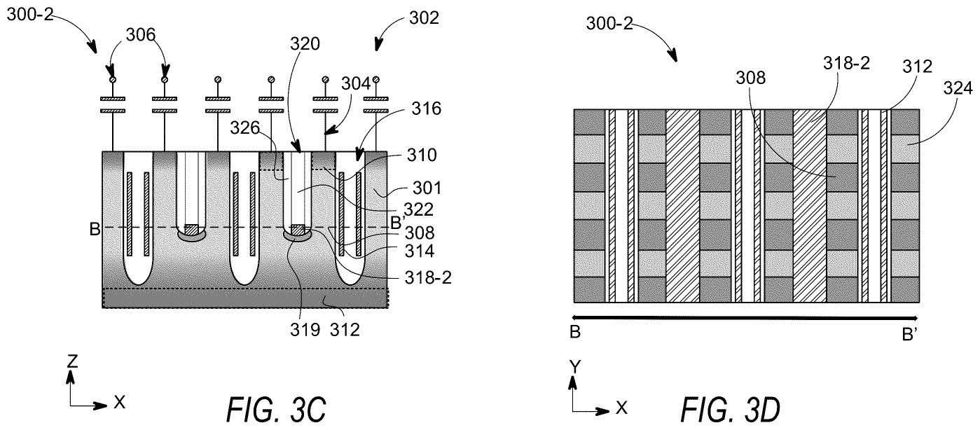

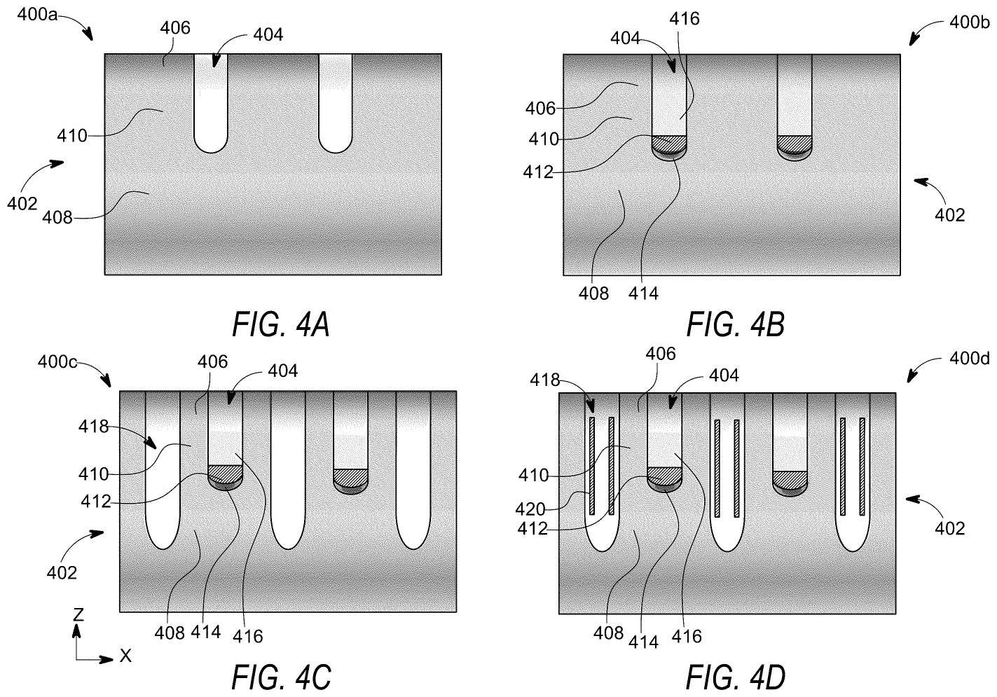

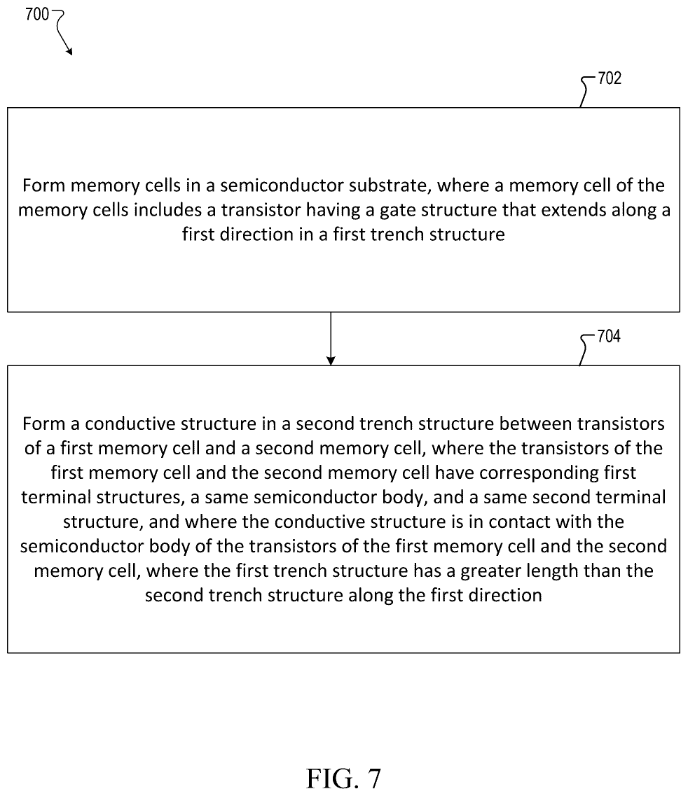

FIG. 3A illustrates a cross-sectional view of an example 3D semiconductor device 300-1. FIG. 3B illustrates a top view of the example 3D semiconductor device 300-1 of FIG. 3A along cut line AA′ of FIG. 3A. The 3D semiconductor device 300-1 can be the 3D semiconductor device 200 of FIG. 2 or the 3D semiconductor device 100 of FIG. 1 or a structure at an intermediate fabrication process of the 3D semiconductor device 100 of FIG. 1. The 3D semiconductor device 300-1 can be formed by methods and/or processes described with further details in FIGS. 4A-4D, and/or FIG. 7.

As illustrated in FIG. 3A, the 3D semiconductor device 300-1 has a semiconductor substrate 301 that includes a semiconductor material (e.g., silicon). An array of memory cells 302 can be formed in the semiconductor substrate 301. The memory cells 302 can be similar to, or same as the memory cells 124 of the semiconductor device 100 of FIG. 1 and the memory cells 202 of the semiconductor device 200 of FIG. 2. Each memory cell 302 can be a DRAM memory cell including a vertical transistor 304 (e.g., the vertical transistor 126 of FIG. 1 or the vertical transistor 204 of FIG. 2) and a capacitor 306 (e.g., the capacitor 128 of FIG. 1) coupled to the vertical transistor 304. The vertical transistor 304 can include a semiconductor body 308 (e.g., the semiconductor body 130 of FIG. 1 or the semiconductor body 206 of FIG. 2), a first terminal structure 310 (e.g., the first terminal structure 156 of FIG. 1 or the first terminal structure 208 of FIG. 2), a second terminal structure 312 (e.g., the second terminal structure 158 of FIG. 1 or the second terminal structure 210 of FIG. 2), and a gate structure 314 (e.g., the gate structure 136 of FIG. 1 or the gate structure 212 of FIG. 2). In some implementations, the gate structure 314 extends along a vertical direction (e.g., the Z direction) in a first trench structure 316. In some implementations, the first trench structure is filled with an isolation material (e.g., SiO2). In some implementations, the first trench structure 316 can be similar to, or same as the first trench structure 132 of the semiconductor device 100 of FIG. 1 and the first trench structure 213 of the semiconductor device 200 of FIG. 2. One of the first terminal structure 310 and the second terminal structure 312 can be a source structure and coupled to a storage node and the other of the first terminal structure 310 and the second terminal structure 312 can be coupled a drain structure and coupled to bit lines.

The semiconductor body 308 can include a semiconductor material, such as single crystalline silicon, polysilicon, amorphous silicon, Ge, any other semiconductor materials, or any combinations thereof. In one example, the semiconductor body 308 may include single crystalline silicon. As discussed with further details below, each of the first terminal structure 310 and the second terminal structure 312 can be formed by implanting N+ type ions (e.g., P or As) or P-type ions (e.g., B or Ga) at a desired doping level into an end of the semiconductor body 308. In one example, the first terminal structure 310 represents a source structure, and the second terminal structure 312 represents a drain structure.

The semiconductor device 300-1 can include a conductive structure 318-1 in a second trench structure 320 between the vertical transistors 304 of the two adjacent memory cells 302. The conductive structure 318-1 is connected to the semiconductor bodies 308 of the two adjacent memory cells 302. In some implementations, the transistors 304 of two adjacent memory cells 302 have corresponding first terminal structures 310, a same semiconductor body 308, and a same second terminal structure 312, and the conductive structure 318-1 is in contact with the semiconductor body 308 of the transistors 304 of the two adjacent memory cells 302. In some implementations, the bottom end of the first trench structure 316 is farther away from the surface of the semiconductor device 300-1 closer to the first terminal structure 310 than the bottom end of the second trench structure 320 along the Z direction. As shown in FIG. 3A, the conductive structure 318-1 includes a semiconductor material (e.g., polysilicon). In some implementations, the second trench structure 320 can include a dielectric body 322 stacked on top of the conductive structure 318-1 along the Z direction. In some implementations, a thickness of the dielectric body 322 is greater than a thickness of the first terminal structure 310 along the Z direction. In some implementations, the conductive structure 318-1 is isolated from the first terminal structure 310 by the dielectric body 322 from the X direction. In some implementations, the conductive structure 318-1 is separate from each of the first terminal structure 310 and the second terminal structure 312 along the Z direction. In some implementations, as shown in FIG. 3A, the semiconductor device 300-1 can include a conductive contact 317 between the conductive structure 318-1 and the semiconductor body 308. In some implementations, the semiconductor bodies 308 of the two adjacent memory cells 302 form a single semiconductor body 308. In some implementations, the second trench structure 320 is surrounded by the single semiconductor body 308. In some implementations, the second terminal structures 312 of the memory cells 302 form a single second terminal structure 312. In some implementations, the transistors of the two adjacent memory cells 302 have respective first terminal structures 310 coupled to respective storage nodes (or capacitors), a same semiconductor body 308, and a same second terminal structure 312.

As shown in FIG. 3B, the semiconductor device 300-1 can include one or more oxide spacers 324 extending along the X direction and being spaced from each other along the Y direction. The one or more oxide spacers 324 the semiconductor device 300-1 into multiple arrays. In some implementations (not shown in FIGS. 3A-3B) the first trench structures 316 and the second trench structures 320 are partially surrounded by the oxide spacer 324. In some implementations, the oxide spacer 324 can be similar to, or same as the third trench structure 220 of the semiconductor device 200 of FIG. 2.

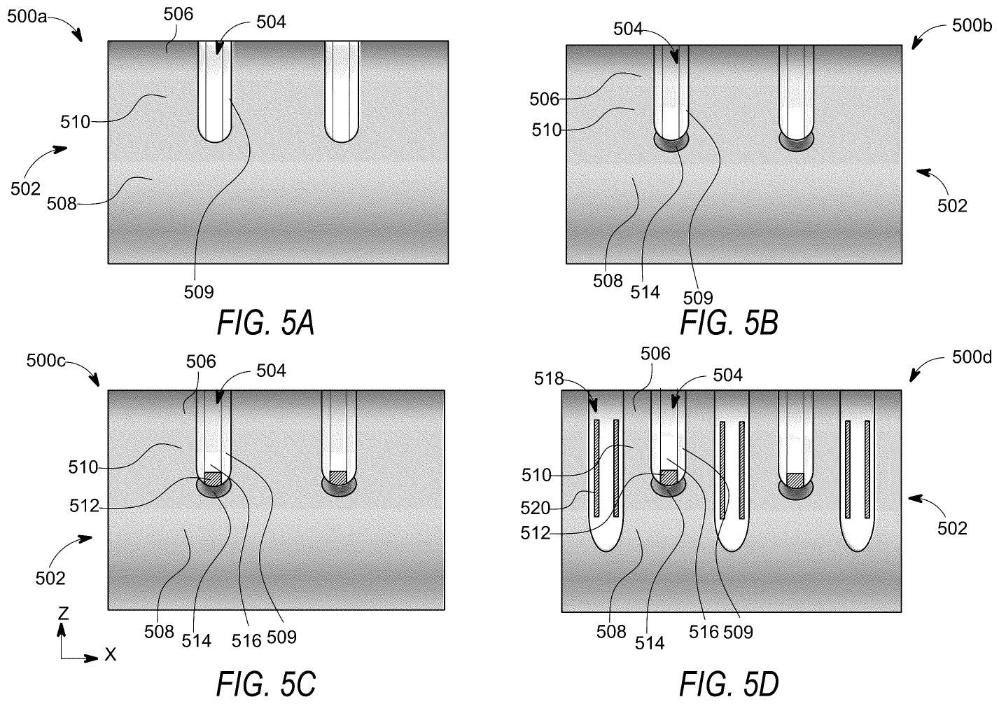

FIG. 3C illustrates a cross-sectional view of an example 3D semiconductor device 300-2. FIG. 3D illustrates a top view of the example 3D semiconductor device 300-2 of FIG. 3C along cut line BB′ of FIG. 3C. The 3D semiconductor device 300-3 can be the 3D semiconductor device 200 of FIG. 2 or the 3D semiconductor device 100 of FIG. 1 or a structure at an intermediate fabrication process of the 3D semiconductor device 100 of FIG. 1. In some implementations, the semiconductor device 300-2 can be similar to the semiconductor device 300-1 of FIG. 3A, except a conductive structure 318-2 of the semiconductor device 300-2 has a different conductive material compared to the conductive structure 318-1 of the semiconductor device 300-1. The 3D semiconductor device 300-2 can be formed by methods and/or processes described with further details in FIGS. 5A-5D, and/or FIG. 7.

In some implementations, as shown in FIG. 3C, the semiconductor device 300-2 can include a conductive structure 318-2 in a second trench structure 320 between the vertical transistors 304 of the two adjacent memory cells 302. The conductive structure is connected to the semiconductor bodies 308 of the two adjacent memory cells 302. In some implementations the transistors 304 of two adjacent memory cells 302 have corresponding first terminal structures 310, a same semiconductor body 308, and a same second terminal structure 312, and the conductive structure 318-2 is in contact with the semiconductor body 308 of the transistors 304 of the two adjacent memory cells 302. In some implementations, the bottom end of the first trench structure 316 is farther away from the surface of the semiconductor device 300-2 closer to the first terminal structure 310 than the bottom end of the second trench structure 320 along the Z direction. As shown in FIG. 3C, the conductive structure 318-2 includes a metallic material (e.g., W). In some implementations, the second trench structure can include a dielectric sidewall 326 coated an inner sidewall of the second trench structure 320. In some implementations, the second trench structure can further include a dielectric body 322 stacked on top of the conductive structure 318-2 along the Z direction. In some implementations, a thickness of the dielectric body 322 is greater than a thickness of the first terminal structure 310 along the Z direction. In some implementations, the conductive structure 318-1 is isolated from the first terminal structure 310 by the dielectric body 322 from the X direction. In some implementations, the conductive structure 318-2 is separate from each of the first terminal structure 310 and the second terminal structure 312 along the Z direction. In some implementations, the semiconductor device 300-2 can include an ohmic contact 319 between the metallic material and the semiconductor body. In some implementations, ohmic contact 319 includes a highly conductive semiconductor material that was diffused into the semiconductor body 308. In some implementations, the dielectric sidewall 326 can include a first direction material and the dielectric body 322 can include a second dielectric material. In some implementations, the first dielectric material is different from the second dielectric material. In some implementations, the semiconductor bodies 308 of the two adjacent memory cells 302 form a single semiconductor body 308. In some implementations, the second trench structure 320 is surrounded by the single semiconductor body 308. In some implementations, the second terminal structures 312 of the memory cells 302 form a single second terminal structure 312. In some implementations, the transistors of the two adjacent memory cells 302 have respective first terminal structures 310 coupled to respective storage nodes (or capacitors), a same semiconductor body 308, and a same second terminal structure 312.

As shown in FIG. 3D, the semiconductor device 300-2 can include one or more oxide spacers 324 extending along the X direction and being spaced from each other along the Y direction. The one or more oxide spacers 324 the semiconductor device 300-2 into multiple arrays. In some implementations (not shown in FIGS. 3C-3D) the first trench structures 316 and the second trench structures 320 are partially surrounded by the oxide spacer 324. In some implementations, the oxide spacer 324 can be similar to, or same as the third trench structure 220 of the semiconductor device 200 of FIG. 2.

FIGS. 4A-4D illustrate an example process of fabricating a semiconductor device, such as the semiconductor device 300-1 as illustrated in FIG. 3A-3B. FIGS. 4A-4D show cross sectional views of example semiconductor structures at various stages of the fabrication process.

As shown in FIG. 4A, a semiconductor structure 400a is formed, which can be formed by etching one or more portions of a semiconductor substrate 402 along a vertical direction (e.g., the Z direction) to form one or more first holes 404. The semiconductor substrate 402 has two ends along the Z direction. In some implementations, the two ends of the semiconductor substrate 402 can be doped with N+ type dopants (e.g., Phosphorus (P) or Arsenic (As)) or P-type dopants (e.g., Boron (B) or Gallium (Ga)) at a desired doping level to form a first terminal structure 406 and a second terminal structure 408. In some implementations, the semiconductor substrate 402 can include a semiconductor body 410 between two terminal structures 406 and 408, where the semiconductor body 410 can be doped with a dopant. The dopant of the semiconductor body 410 is different from the dopant of the terminal structures 406 and 408. In some implementations, the terminal structures 406 and 408 can be doped with N+ type dopants and the semiconductor body can be doped with P-type dopants. In some implementations, the terminal structures 406 and 408 can be doped with P-type dopants and the semiconductor body can be doped with N+ type dopants.

FIG. 4B illustrates a semiconductor structure 400b, which can be formed by depositing a semiconductor material in the one or more first holes 404 along the Z direction to form conductive structures 412, where a thickness of the semiconductor material is no greater than a thickness of the semiconductor body 410 along the Z direction. A portion of the semiconductor material is diffused into the semiconductor body 410 during the deposition process to form a conductive contact 414 between the conductive structure 412 and the semiconductor body 410 along the Z direction. In some implementations, the semiconductor structure 400b can include dielectric bodies 416 stacked on top of the conductive structures 412 in the first trench. The dielectric bodies 416 are formed by filling a remaining portion of the one or more first holes 404 with a dielectric material to form one or more first filled holes 404. In some implementations, an end 412-1 of the conductive structure 412 is farther from a surface of the semiconductor substrate 402 than an end 410-1 of the semiconductor body 410.

FIG. 4C illustrates a semiconductor structure 400c, which can be formed by etching one or more portions of the semiconductor substrate 402 along the Z direction to form one or more second holes 418. The one or more second holes 418 and the one or more first filled holes 404 are separated from each other along a horizontal direction (e.g., the X direction) perpendicular to the Z direction. In some implementations, a length of the one or more second holes 418 is greater than a length of the one or more first filled holes 404 along the Z direction.

FIG. 4D illustrates a semiconductor structure 400d. The semiconductor structure 400d can include gate structures 420. The gate structures can be formed by depositing a conductive material into the one or more second holes 418 and filled the remaining portion of the second holes 418 with a dielectric material to form the one or more second filled holes 418. In some implementations, an end 420-1 of the gate structure 420 is farther from the first terminal structure 406 than an end 404-1 of the one or more first filled holes 404.

FIGS. 5A-5D illustrate an example process of fabricating a semiconductor device, such as the semiconductor device 300-2 as illustrated in FIG. 3C-3D. FIGS. 5A-5D show cross sectional views of example semiconductor structures at various stages of the fabrication process.

As shown in FIG. 5A, a semiconductor structure 500a is formed, which can be formed by etching one or more portions of a semiconductor substrate 502 along a vertical direction (e.g., the Z direction) to form one or more first holes 504. The semiconductor substrate 502 has two ends along the Z direction. In some implementations, the two ends of the semiconductor substrate 502 can be doped with N+ type dopants (e.g., Phosphorus (P) or Arsenic (As)) or P-type dopants (e.g., Boron (B) or Gallium (Ga)) at a desired doping level to form a first terminal structure 506 and a second terminal structure 508. In some implementations, the semiconductor substrate 502 can include a semiconductor body 510 between two terminal structures 506 and 508, where the semiconductor body 510 can be doped with a dopant. The dopant of the semiconductor body 510 is different from the dopant of the terminal structures 506 and 508. In some implementations, the terminal structures 506 and 508 can be doped with N+ type dopants and the semiconductor body can be doped with P-type dopants. In some implementations, the terminal structures 506 and 508 can be doped with P-type dopants and the semiconductor body can be doped with N+ type dopants. The semiconductor structure 500a can include dielectric sidewall 509, which is formed by coating a dielectric material on a sidewall of the one or more first holes 504 and etching through a bottom portion of the dielectric sidewall 509, where the bottom portion of the dielectric sidewall is connected to the semiconductor body 510 along the Z direction.

FIG. 5B illustrates a semiconductor structure 500b, which can be formed by implanting conductive ions into the semiconductor body at a bottom of the one or more first holes 504 to form a conductive contact 514.

FIG. 5C illustrates a semiconductor structure 500c, which can be formed by depositing a metallic material in the one or more first holes 504 on top of the conductive contact 514 along the Z direction to form conductive structures 512, where a thickness of the metallic material is no greater than a thickness of the semiconductor body 510 along the Z direction. In some implementation, the metallic material and the conductive contact 514 formed an ohmic contact. In some implementations, the semiconductor structure 500c can include dielectric bodies 516 stacked on top of the conductive structure 512 in the first trench. The dielectric bodies 516 are formed by filling a remaining portion of the one or more first holes 504 with a dielectric material to form one or more first filled holes 504. In some implementations, an end 512-1 of the conductive structure 512 is farther from a surface of the semiconductor substrate 502 than an end 510-1 of the semiconductor body 510.

FIG. 5D illustrates a semiconductor structure 500d, which can be formed by etching one or more portions of the semiconductor substrate 502 along the Z direction to form one or more second holes 518. The one or more second holes 518 and the one or more first filled holes 504 are separated from each other along a horizontal direction (e.g., the X direction) perpendicular to the Z direction. In some implementations, a length of the one or more second holes 518 is greater than a length of the one or more first filled holes 504 along the Z direction. The semiconductor structure 500d can include gate structures 520. The gate structures can be formed by depositing a conductive material into the one or more second holes 518 and filled the remaining portion of the second holes 518 with a dielectric material to form one or more second filled holes 518. In some implementations, an end 520-1 of the gate structure 520 is farther from the first terminal structure 506 than an end 504-1 of the one or more first filled holes 504.

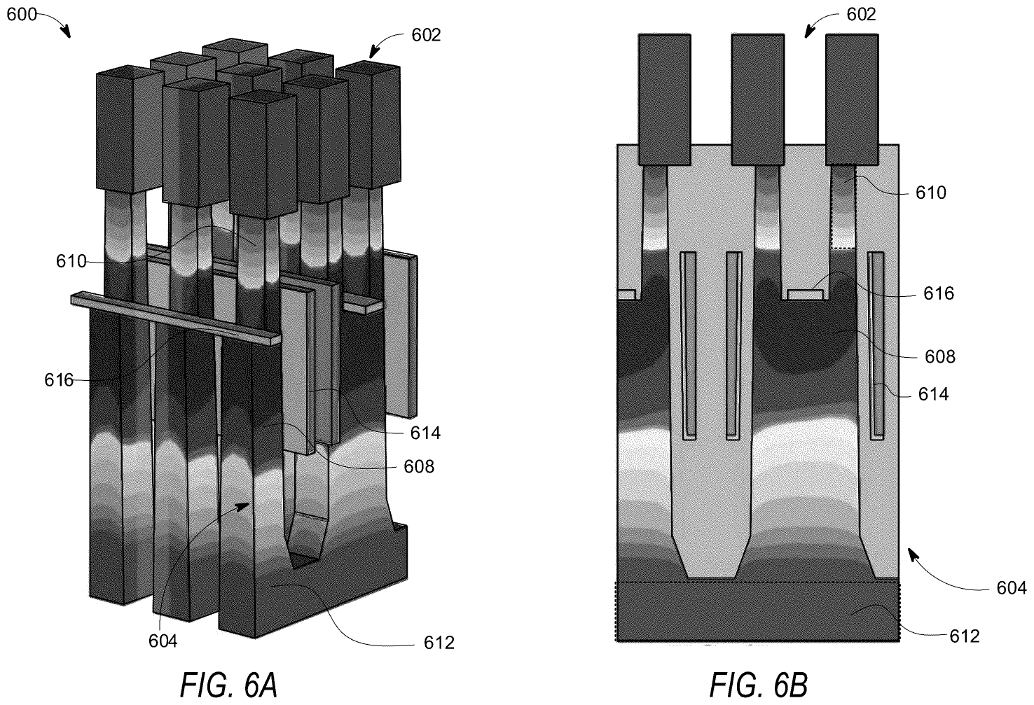

FIGS. 6A-6B illustrate a perspective view of an example 3D semiconductor device 600. The 3D semiconductor device 600 can be the 3D semiconductor device 200 of FIG. 2 or the 3D semiconductor device 100 of FIG. 1 or a structure at an intermediate fabrication process of the 3D semiconductor device 100 of FIG. 1.

As shown in FIGS. 6A-6B, the semiconductor 600 can include multiple memory cells 602. The memory cells 602 can be similar to, or same as the memory cells 124 of the semiconductor device 100 of FIG. 1, the memory cells 202 of the semiconductor device 200 of FIG. 2 and the memory cell 302 of the semiconductor device 300-1 of FIGS. 3A-3D. Each memory cell 602 can be a DRAM memory cell including a vertical transistor 604 (e.g., the vertical transistor 126 of FIG. 1, the vertical transistor 204 of FIG. 2 or the vertical transistor 304 of FIGS. 3A-3D). The vertical transistor 604 can include a semiconductor body 608 (e.g., the semiconductor body 130 of FIG. 1, the semiconductor body 206 of FIG. 2 or the semiconductor body 308 of FIG. 3A-3D), a first terminal structure 610 (e.g., the first terminal structure 156 of FIG. 1, the first terminal structure 208 of FIG. 2 or the first terminal structure 310 of FIG. 3A-3D), a second terminal structure 612 (e.g., the second terminal structure 158 of FIG. 1, the second terminal structure 210 of FIG. 2 or the second terminal structure 312 of FIG. 3A-3D), and a gate structure 614 (e.g., the gate structure 136 of FIG. 1, the gate structure 212 of FIG. 2, or gate structure 314 of FIG. 3A-3D). In some implementations, the semiconductor device 600 can include a conductive structure 616 in between vertical transistors 304 of the two adjacent memory cells 602. In some implementations, the conductive structure 316 is connected to the semiconductor bodies 608 of the vertical transistors 604 of the two adjacent memory cells 602. In some implementations, the conductive structure 616 is similar to, or same as the conductive structure 160 of the semiconductor 100 of FIG. 1 or the conductor structure 214 of the semiconductor 200 of FIG. 2.

In some implementations, a range of a first leakage current from the first terminal structure 610 is between 1×10⁻¹⁸ A and 1×10⁻¹⁶ A, and a second leakage current from the second terminal structure 612 is lower than 5×10⁻¹⁵ A when the memory cell 602 is configured to store a first programming level. In some implementations, the range of a first leakage current from the first terminal structure 610 is lower than 1×10⁻¹⁴ A, and the second leakage current from the second terminal structure 612 is between 1×10⁻¹⁸ A and 1×10⁻¹⁶ A when the memory cell 602 is configured to store a second programming level.

FIG. 7 illustrates a flow chart of an example process 700. The process 700 can be performed to form a semiconductor device (e.g., the semiconductor device 300-1 illustrated by FIGS. 3A-3B or the semiconductor device 300-2 illustrated by FIGS. 3C-3D). The process 700 can be described in view of FIG. 4A-4D or FIG. 5A-5D. The process 700 can include one or more steps of the fabrication process of forming the semiconductor structures in FIG. 4A-4D or FIG. 5A-5D. It is understood that the operations shown in process 700 are not exhaustive and that other operations can be performed as well before, after, or between any of the illustrated operations. Further, some of the operations may be performed simultaneously, or in a different order than shown in FIG. 7.

At operation 702, a semiconductor structure (e.g., the semiconductor structure 400d or FIG. 4D or semiconductor structure 500d of FIG. 5D) is formed. The semiconductor structure includes a plurality of memory cells (e.g., the memory cells 124 in FIG. 1, the memory cells in FIG. 2 or the memory cells 302 in FIGS. 3A-3D) in a semiconductor substrate (e.g. the semiconductor substrate 402 in FIG. 4A or the semiconductor substrate 502 in FIG. 5A), where a memory cell of the plurality of memory cells includes a transistor (e.g., the vertical transistor 126 in FIG. 1, the vertical transistor 204 in FIG. 2 or the vertical transistor 304 in FIGS. 3A-3D) having a gate structure (e.g. the gate structure 420 in FIG. 4D or the gate structure 520 in FIG. 5D) that extends along a first direction (e.g., the Z direction) in a first trench structure (e.g., the one or more second filled holes 418 in FIG. 4D or the one or more second filled holes 518 in FIG. 5D).

At operation 704, a conductive structure (e.g. the conductive structure 412 in FIG. 4B or the conductive structure 512 in FIG. 5C) in a second trench structure (e.g. the one or more first filled holes 404 in FIG. 4B or the one or more first filled holes 504 in FIG. 5B) between transistors of a first memory cell (e.g., the first memory cell 124a in FIG. 1) and a second memory cell (e.g., the second memory cell 124b in FIG. 1) is formed, where the transistors of the first memory cell and the second memory cell have corresponding first terminal structures (e.g. the first terminal structure 406 in FIG. 4A or the first terminal structure 506 in FIG. 5A), a same semiconductor body (e.g. the semiconductor body 410 in FIG. 4A or the semiconductor body 510 in FIG. 5A), and a same second terminal structure (e.g. the second terminal structure 408 in FIG. 4A or the second terminal structure 508 in FIG. 5A), and where the conductive structure is in contact with the semiconductor body of the transistors of the first memory cell and the second memory cell, where the first trench structure has a greater length than the second trench structure along the first direction.

In some implementations, the semiconductor body of the memory cell includes opposite ends along the first direction and opposite sides along a second direction (e.g., the X direction) perpendicular to the first direction, where the first terminal structure and the second terminal structure are at the opposite ends of the semiconductor body, respectively, and where the first trench structure and the second trench structure are at the opposite sides of the semiconductor body, respectively.

In some implementations, forming the conductive structure includes etching the semiconductor substrate along the first direction to form a trench (e.g., the one or more second holes 418 in FIG. 4C) in contact with the semiconductor body; and depositing a semiconductor material in the trench along the first direction, where a thickness of the semiconductor material is no greater than a thickness of the semiconductor body along the first direction.

In some implementations, a portion of the semiconductor material is diffused into the semiconductor body to form a conductive contact (e.g., the conductive contact 414 of FIG. 4B) between the semiconductor material and the semiconductor body, and where the conductive structure is in contact with a part of the semiconductor body that is closer to the second terminal structure than the first terminal structure along the first direction.

In some implementations, forming the conductive structure includes etching the semiconductor substrate along the first direction to form a trench (e.g., the one or more second holes 518 in FIG. 5D) in contact with the semiconductor body; implanting conductive ions into the semiconductor body at a bottom of the trench to form a conductive contact (e.g., the conductive contact 514 of FIG. 5C); and depositing a metallic material on the conductive contact in the trench to form the conductive structure, where a thickness of the metallic material is no greater than a thickness of the semiconductor body along the first direction.

In some implementations, the process 700 further includes forming the first trench structure including the gate structure, where the first trench structure and the second trench structure are at different positions along a second direction perpendicular to the first direction, and where the gate structure extends along the first direction in the first trench structure, and where, along the first direction, an end of the gate structure of the vertical transistor of the memory cell is farther from the first terminal structure of the vertical transistor of the memory cell than an end of second trench structure.

In some implementations, the first trench structure and the second trench structure extend along a second direction perpendicular (e.g., the Y direction) to the first direction, and where the method further includes forming one or more third trench structures (e.g., the one or more third trench structures 220 in FIG. 2) extending through the semiconductor substrate along the first direction and being spaced from each other along a third direction perpendicular to the first direction and the second direction.

In some implementations, the one or more third trench structures are filled with an isolating material, and where the first trench structure includes the isolating material filled around the gate structure, and the second trench structure includes the isolating material stacked on the conductive structure along the first direction.

In some implementations, the process 700 further includes forming a coupling-out structure (e.g., the coupling-out structure 218 in FIG. 2), where the conductive structure in the second trench structure is coupled to an interconnect structure through the coupling-out structure.

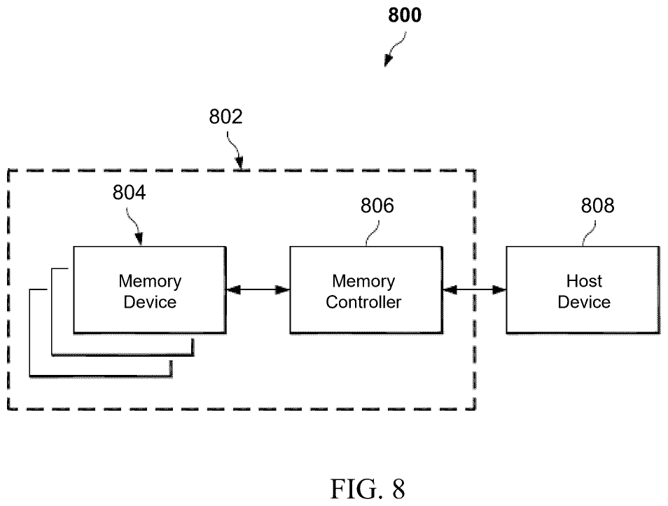

FIG. 8 illustrates a block diagram of a system 800 having one or more semiconductor devices (e.g., memory devices), according to one or more implementations of the present disclosure. The system 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, the system 800 can include a host device 808 and a memory system 802 having one or more 3D memory devices 804 and a memory controller 806. Host device 808 can include a processor of an electronic device, such as a central processing unit (CPU), or a system-on-chip (SoC), such as an application processor (AP). Host device 808 can be configured to send or receive data to or from the one or more 3D memory devices 804.

A 3D memory device 804 can be any 3D memory device disclosed herein, such as a 3D memory device depicted in FIGS. 1, 2, 3A-3B, 3C-3D, 4A-4D, 5A-5B, or 6A-6B. In some implementations, a 3D memory device 804 includes a DRAM memory. Memory controller 806 (a.k.a., a controller circuit) is coupled to 3D memory device 804 and host device 808. Consistent with implementations of the present disclosure, 3D memory device 804 can include a plurality of conductive interconnections through a cover layer that are in contact with conductive pads in a conductive pad layer, and memory controller 806 can be coupled to 3D memory device 804 through at least one of the plurality of conductive interconnections. Memory controller 806 is configured to control 3D memory device 804. For example, memory controller 806 may be configured to operate a plurality of channel structures via word lines. Memory controller 806 can manage data stored in 3D memory device 804 and communicate with host device 808.

In some implementations, memory controller 806 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 806 can be configured to control operations of 3D memory device 804, such as read, erase, and program (or write) operations. Memory controller 806 can also be configured to manage various functions with respect to the data stored or to be stored in 3D memory device 804 including, but not limited to bad-block management, garbage collection, logical-to-physical address conversion, wear leveling, etc. In some implementations, memory controller 806 is further configured to process error correction codes (ECCs) with respect to the data read from or written to 3D memory device 804. Any other suitable functions may be performed by memory controller 806 as well, for example, formatting 3D memory device 804.

Memory controller 806 can communicate with an external device (e.g., host device 808) according to a particular communication protocol. For example, memory controller 806 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more 3D memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 8, memory controller 806 and a single 3D memory device 804 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g.,. +-.10%,. +-.20%, or. +-.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a plurality of memory cells, wherein a memory cell of the plurality of memory cells comprises a transistor having a gate structure that extends along a first direction in a first trench structure; and
a conductive structure in a second trench structure between transistors of a first memory cell and a second memory cell, wherein the transistors of the first memory cell and the second memory cell have corresponding first terminal structures, a same semiconductor body, and a same second terminal structure, and wherein the conductive structure is in contact with the semiconductor body of the transistors of the first memory cell and the second memory cell,
wherein the first trench structure has a greater length than the second trench structure along the first direction.

2. The semiconductor device of claim 1, wherein, along the first direction, an end of the gate structure of the transistor of the memory cell is farther from the first terminal structure of the transistor of the memory cell than an end of the second trench structure.

3. The semiconductor device of claim 1, wherein a length of the first trench structure is greater than a length of the second trench structure along a second direction perpendicular to the first direction.

4. The semiconductor device of claim 1, wherein the semiconductor body of the memory cells comprises opposite ends along the first direction,
wherein the first terminal structure and the second terminal structure are at the opposite ends of the semiconductor body of the memory cell, respectively, and
wherein the second trench structure is between two adjacent first trench structures along a second direction perpendicular to the first direction.

5. The semiconductor device of claim 1, wherein the semiconductor device comprises a third memory cell, wherein the first memory cell is between the second memory cell and the third memory cell along a second direction perpendicular to the first direction, and
wherein the first trench structure comprises two gate structures of two transistors of the first memory cell and the third memory cell, wherein the two gate structures are isolated by an isolation material filled in the first trench structure.

6. The semiconductor device of claim 1, wherein the conductive structure is isolated from the first terminal structure by a dielectric material along a second direction perpendicular to the first direction.

7. The semiconductor device of claim 1, wherein the conductive structure comprises a semiconductor material, and
wherein the second trench structure further comprises a dielectric body stacked on the conductive structure along the first direction.

8. The semiconductor device of claim 1, wherein the conductive structure comprises a metallic material,
wherein the second trench structure further comprises a dielectric body stacked on the conductive structure along the first direction, and
wherein the semiconductor device further comprises an ohmic contact between the metallic material and the semiconductor body.

9. The semiconductor device of claim 1, wherein the conductive structure in the second trench structure is coupled to an interconnect structure through a coupling-out structure.

10. The semiconductor device of claim 1, wherein the first trench structure and the second trench structure extend along a second direction perpendicular to the first direction, and
wherein the semiconductor device further comprises one or more third trench structures extending through the semiconductor device along the first direction and being spaced from each other along a third direction perpendicular to the first direction and the second direction.

11. The semiconductor device of claim 10, wherein the one or more third trench structures are filled with an isolating material, and wherein the first trench structure comprises the isolating material filled around the gate structure, and the second trench structure comprises the isolating material stacked on the conductive structure along the first direction.

12. A method of forming a semiconductor device, the method comprising:
forming a plurality of memory cells in a semiconductor substrate, wherein a memory cell of the plurality of memory cells comprises a transistor having a gate structure that extends along a first direction in a first trench structure; and
forming a conductive structure in a second trench structure between transistors of a first memory cell and a second memory cell, wherein the transistors of the first memory cell and the second memory cell have corresponding first terminal structures, a same semiconductor body, and a same second terminal structure, and wherein the conductive structure is in contact with the semiconductor body of the transistors of the first memory cell and the second memory cell,
wherein the first trench structure has a greater length than the second trench structure along the first direction.

13. The method of claim 12, wherein the semiconductor body of the memory cells comprises opposite ends along the first direction,
wherein the first terminal structure and the second terminal structure are at the opposite ends of the semiconductor body of the memory cell, respectively, and
wherein the second trench structure is between two adjacent first trench structures along a second direction perpendicular to the first direction.

14. The method of claim 12, wherein forming the conductive structure comprises:
etching the semiconductor substrate along the first direction to form a trench; and
depositing a semiconductor material in the trench along the first direction, wherein a length of the semiconductor material is no greater than a length of the semiconductor body along the first direction.

15. The method of claim 14, wherein a portion of the semiconductor material is diffused into the semiconductor body to form a conductive contact between the semiconductor material and the semiconductor body, and wherein the conductive structure is in contact with a part of the semiconductor body that is closer to the second terminal structure than the first terminal structure along the first direction.

16. The method of claim 12, wherein forming the conductive structure comprises:
etching the semiconductor substrate along the first direction to form a trench;
implanting conductive ions into the semiconductor body at a bottom of the trench to form a conductive contact; and
depositing a metallic material on the conductive contact in the trench to form the conductive structure,
wherein a length of the metallic material is no greater than a length of the semiconductor body along the first direction.

17. The method of claim 12, further comprising:
forming the first trench structure comprising the gate structure, wherein the first trench structure and the second trench structure are at different positions along a second direction perpendicular to the first direction, and
wherein the gate structure extends along the first direction in the first trench structure, and wherein, along the first direction, an end of the gate structure of the transistor of the memory cell is farther from the first terminal structure of the transistor of the memory cell than an end of the second trench structure.

18. The method of claim 12, wherein the first trench structure and the second trench structure extend along a second direction perpendicular to the first direction, and
wherein the method further comprises:
forming one or more third trench structures extending through the semiconductor substrate along the first direction and being spaced from each other along a third direction perpendicular to the first direction and the second direction.

19. The method of claim 12, further comprising:
forming a coupling-out structure, where the conductive structure in the second trench structure is coupled to an interconnect structure through the coupling-out structure.

20. A memory system, comprising:
a memory device; and
a memory controller coupled to the memory device and configured to control the memory device,
wherein the memory device comprises:
a plurality of memory cells, wherein a memory cell of the plurality of memory cells comprises a transistor having a gate structure that extends along a first direction in a first trench structure; and
a conductive structure in a second trench structure between transistors of a first memory cell and a second memory cell, wherein the transistors of the first memory cell and the second memory cell have corresponding first terminal structures, a same semiconductor body, and a same second terminal structure, and wherein the conductive structure is in contact with the semiconductor body of the transistors of the first memory cell and the second memory cell,
wherein the first trench structure has a greater length than the second trench structure along the first direction.
